(19) United States
(12) Patent Application Publication
(10) Pub. No.: US 2012/0325655 A1
(43) Pub. Date: Dec. 27, 2012

(54) A1-BASED ALLOY SPUTTERING TARGET

(75) Inventors: Yuki Iwasaki, Kobe-shi (JP); Katsushi Matsumoto, Kobe-shi (JP); Toshiaki Takagi, Kobe-shi (JP); Mamoru Nagao, Kobe-shi (JP); Hidetada Makino, Takasago-shi (JP)

(73) Assignees: Kobelco Research Institute Inc., Hyogo (JP); Kabushiki Kaisha Kobe Seiko Sho (Kobe Steel, Ltd.), Hyogo (JP)

(21) Appl. No.: 13/581,436

(22) PCT Filed: Feb. 25, 2011
(86) PCT No.: PCT/JP2011/054396

§ 371 Date: Aug. 27, 2012

(30) Foreign Application Priority Data
Feb. 26, 2010 (JP) 2010-043073

(51) Int. Cl. C23C 14/34

(52) U.S. Cl. 204/298.13

(57) ABSTRACT

The present invention provides a technique capable of suppressing generation of splash even at high-speed deposition by an Al-based alloy sputtering target containing Ni and a rare earth element, wherein when crystallographic orientations <001>, <011>, <111>, <012> and <112> in a normal direction of each sputtering surface at a surface part of the Al-based alloy sputtering target, a ¼×t (t: thickness of the Al-based alloy sputtering target) part thereof and a ½×t part thereof are observed by an electron backscatter diffraction pattern method, the Al-based alloy sputtering target satisfies the requirement (1) that, when a total of area fractions of the <001>±15°, <011>±15° and <112>±15° is defined as R (as for Rat each part, the R at the surface part is defined as Rₐ, the R at the ¼×t part is defined as R_{b}, and the R at the ½×t part is defined as R_{c}), R is 0.35 or more and 0.80 or less; and the requirement (2) that each of the Rₐ, the R_{b} and the R_{c} falls in the range of ±20% of an average R value [Rₐᵥₑ=(Rₐ+R_{b}+R_{c})/3].

### TECHNICAL FIELD

The present invention relates to an Al-based alloy sputtering target containing Ni and a rare earth element. More specifically, the present invention relates to a Ni-rare earth element-Al-based alloy sputtering target in which the crystallographic orientation in the normal direction of the sputtering surface is controlled. In the following, the Al-based alloy containing Ni and a rare earth element is sometimes referred to as “Ni-rare earth element-Al-based alloy” or simply as “Al-based alloy”.

### BACKGROUND ART

An Al-based alloy, being low in electrical resistivity and easy to process, is widely used in a field of: flat panel displays (FPD) such as liquid crystal displays (LCD), plasma display panels (PDP), electroluminescence displays (ELD), field emission displays (FED) and micro electro mechanical systems (MEMS); touch panel; and electronic paper, and is used as materials for interconnection films, electrode films and reflective electrode films.

For example, an active matrix type liquid crystal display includes a thin film transistor (TFT) that is a switching element, a pixel electrode made of a conductive oxide film and a TFT substrate having an interconnection containing a scanning line and a signal line, and the scanning line, the signal line being electrically connected to the pixel electrode. As an interconnection material that constitutes the scanning line and signal line, generally, thin films of a pure Al or an Al—Nd alloy are used. However, when the thin films are directly connected to the pixel electrode, insulating aluminum oxide is formed at an interface thereof to increase the electrical contact resistance. Accordingly, so far, a barrier metal layer made of a refractory metal such as Mo, Cr, Ti or W has been disposed between the Al interconnection material and the pixel electrode to reduce the electrical contact resistance.

However, in a method of interposing a barrier metal layer such as mentioned above, there is a problem in that a production process becomes troublesome to be high in the production cost.

Then, there has been proposed, as a technology that, without interposing a barrier metal layer, enables to directly connect an electroconductive oxide film that constitutes a pixel electrode and an interconnection material (direct contact technology), a method in which as an interconnection material a thin film of a Ni—Al-based alloy or a Ni-rare earth element-Al-based alloy further containing a rare earth element such as Nd or Y is used (see, Patent Document 1). When Ni—Al-based alloy is used, at the interface, an electroconductive Ni-containing precipitates are formed to suppress insulating aluminum oxide from generating; accordingly, the electrical resistance can be suppressed low. Furthermore, when Ni-rare earth element-Al-based alloy is used, the heat resistance can be further improved.

When an Al-based alloy thin film is formed, in general, a sputtering method that uses a sputtering target has been adopted. According to the sputtering method, plasma discharge is generated between a substrate and a sputtering target (target material) constituted of a raw material substance of a thin film material, a gas ionized by the plasma discharge is brought into collision with the target material to knock out atoms of the target material to deposit on the substrate to produce a thin film. The sputtering method, different from a vacuum deposition method and an arc ion plating method (AIP), has an advantage in that a thin film having a composition same as that of the target material can be formed. In particular, an Al-based alloy thin film deposited by use of the sputtering method can dissolve an alloy element such as Nd that cannot be dissolved in an equilibrium state and thereby can exert excellent performance as a thin film; accordingly, the sputtering method is an industrially effective thin film producing method and a development of a sputtering target material that is a raw material thereof has been forwarded.

Recently, in order to cope with the productivity enlargement of FPDs, a deposition rate during a sputtering step tends to be increased more than ever. In order to increase the deposition rate, the sputtering power can be most conveniently increased. However, when the sputtering power is increased, sputtering defects such as arcing (irregular discharge) or splash (fine melt particles) are caused to generate defects in the interconnection film; accordingly, harmful effects such as deteriorating the yield and operation performance of the FPDs are caused.

In order to inhibit the sputtering defects from occurring, for example, methods described in Patent Documents 2 to 5 have been proposed. Among these, in Patent Documents 2 to 4 that are based on the viewpoint in that the splash is caused owing to fine voids in a target material texture, a dispersion state of particles of a compound of Al and a rare earth element in an Al matrix is controlled (Patent Document 2), a dispersion state of a compound of Al and a transition metal element in an Al matrix is controlled (Patent Document 3) or a dispersion state of an intermetallic compound between an additive element and Al in a target is controlled (Patent Document 4) to inhibit the splash from occurring. Furthermore, Patent Document 5 discloses a technology in which the hardness of a sputtering surface is controlled, followed by applying finish machine working to inhibit surface defects due to the machine working from occurring and thereby the arcing generated during the sputtering is reduced.

On the other hand, Patent Document 6 describes a technique for preventing generation of splash, where an ingot mainly composed of Al is rolled into plate form at a working ratio of 75% or less in a temperature range of 300 to 450° C. and then heat-treated at a temperature of more than the rolling temperature and 550° C. or less, and by using the rolled surface side as the sputtering surface, the Vickers hardness of the obtained sputtering target such as Ti—W—Al-based alloy is controlled to 25 or less.

Furthermore, Patent Document 7 discloses a method in which a ratio of crystallographic orientations in a sputtering surface of a sputtering target is controlled to enable to sputter at a high deposition rate. It is described that when a content of a <111> crystallographic orientation when a sputtering surface is measured by X-ray diffractometry is made such high as 20% or more, a ratio of a target material flying in a direction vertical to the sputtering surface increases and thereby a thin film deposition rate is increased. In a column of examples of Patent Document 7, results when an Al-based alloy target containing 1 mass % of Si and 0.5 mass % of Cu is used are described.

On the other hand, a technique for suppressing generation of a sputtering defect even at a high deposition rate is also disclosed (Patent Document 8). In the technique proposed by Patent Document 8, a Ni-containing Al-based alloy sputtering target produced by a spray forming method is concerned and controlled such that when measured by an electron backscatter diffraction pattern method, the total of area fractions (P value) of crystallographic orientations <001>, <011>, <111> and <311> in the normal direction of the sputtering surface is 70% or more based on the entire area of the sputtering surface and the ratios of area fractions of <011> and <111> to the P value are 30% or more and 10% or less, respectively, whereby a sputtering defect such as arcing (abnormal discharge) is prevented.

A technique for enhancing the microscopic smoothness of the finish surface in order to keep the sputtering target surface clean is also disclosed (Patent Document 9). In the technique proposed by Patent Document 9, the Vickers hardness (HV) of an Al—(Ni, Co)—(Cu,Ge)—(La,Gd,Nd)-based alloy sputtering target produced by a spray forming method is controlled to 35 or more so as to improve processability during machining and enhance the microscopic smoothness of the finish surface, whereby generation of splash at the initial stage of using the sputtering target is reduced.

### PRIOR ART DOCUMENTS

### Patent Documents

Patent Document 1: JP-A-2004-214606
Patent Document 2: JP-A-10-147860
Patent Document 3: JP-A-10-199830
Patent Document 4: JP-A-11-293454
Patent Document 5: JP-A-2001-279433
Patent Document 6: JP-A-9-235666
Patent Document 7: JP-A-6-128737
Patent Document 8: JP-A-2008-127623
Patent Document 9: JP-A-2009-263768

### SUMMARY OF THE INVENTION

### Problems that the Invention is to Solve

As described above, sputtering defect such as splash or arcing brings about reduction in the yield and productivity of FPD and particularly, in the case of using a sputtering target at a high deposition rate, involves a serious problem. For improving the sputtering defect and enhancing the deposition rate, various techniques have been heretofore proposed, but more improvements are demanded.

Among Al-based alloys, as to an Al-based alloy sputtering target used in the formation of a Ni-rare earth element-Al-based alloy thin film useful for the above-described direct contact technology, a technique capable of effectively preventing generation of splash even at high-speed deposition is demanded.

In the method described in Patent Document 8, a sputtering target which is obtained by a spray forming method and has a fine grain size is concerned, and since the spray forming method has a problem of high production cost, further improvements are demanded.

Under these circumstances, the present invention has been made, and an object of the present invention is to provide a technique ensuring that in the case of using a Ni-rare earth element-Al-based alloy sputtering target, generation of splash can be suppressed even at high-speed deposition of 2.2 nm/s or more.

### Means for Solving the Problems

The present invention encompasses the following embodiments.

[1] An Al-based alloy sputtering target containing Ni and a rare earth element, wherein when crystallographic orientations <001>, <011>, <111>, <012> and <112> in a normal direction of each sputtering surface at a surface part of the Al-based alloy sputtering target, a ¼×t (t: thickness of the Al-based alloy sputtering target) part thereof and a ½×t part thereof are observed by an electron backscatter diffraction pattern method, the Al-based alloy sputtering target satisfies the following requirements (1) and (2):

(1) when a total of area fractions of the <001>±15°, <011>±15° and <112>±15° is defined as R (as for Rat each part, the R at the surface part is defined as Rₐ, the R at the ¼×t part is defined as R_{b}, and the R at the ½×t part is defined as R_{c}), R is 0.35 or more and 0.80 or less; and

(2) each of the Rₐ, the R_{b} and the R_{c} falls in the range of ±20% of an average R value [Rₐᵥₑ=(Rₐ+R_{b}+R_{c})/3].

[2] The Al-based alloy sputtering target according to [1], wherein when the sputtering surface of the Al-based alloy sputtering target is observed by the electron backscatter diffraction pattern method to observe a grain size, an average grain size is from 40 to 450 μm.

[3] The Al-based alloy sputtering target according to [1] or [2], wherein a content of the Ni is from 0.05 to 2.0 atomic %, and a content of the rare earth element is from 0.1 to 1.0 atomic %.

[4] The Al-based alloy sputtering target according to any one of [1] to [3], which further contains Ge.

[5] The Al-based alloy sputtering target according to [4], wherein a content of the Ge is from 0.10 to 1.0 atomic %.

[6] The Al-based alloy sputtering target according to any one of [1] to [5], which further contains Ti and B.

[7] The Al-based alloy sputtering target according to [6], wherein a content of the Ti is from 0.0002 to 0.012 atomic %, and a content of the B is from 0.0002 to 0.012 atomic %.

[8] The Al-based alloy sputtering target according to any one of [1] to [7], wherein a Vickers hardness of the Al-based alloy sputtering target is 26 or more.

### Advantage of the Invention

In the Ni-rare earth element-Al-based alloy target of the present invention, the crystallographic orientation in the normal direction of the sputtering surface is appropriately controlled, so that even when deposition is performed at a high speed, the deposition rate can be stabilized and sputtering defect (splash) can be also effectively reduced. In this way, according to the present invention, the deposition rate can be stably maintained from the start to the substantial end of use of the target, so that splash generated during the deposition of the sputtering target or variability of the deposition rate can be greatly reduced and the productivity can be enhanced.

### BRIEF DESCRIPTION OF THE DRAWINGS

FIG. 1 illustrates the Face Centered Cubic (FCC) lattice together with representative crystallographic orientations.

FIG. 2A is an inverse pole figure map at the ¼×t part of the sputtering target of Example No. 4.

FIG. 2B is an inverse pole figure map at the ¼×t part of the sputtering target of Example No. 5.

FIG. 2C is an inverse pole figure map at the ¼×t part of the sputtering target of Example No. 9.

### EMBODIMENTS FOR CARRYING OUT THE INVENTION

The present inventors have made intensive studies to provide an Al-based alloy sputtering target capable of reducing splash that is generated during the sputtering deposition. Above all, in the present invention, studies have been made to provide a technique where a Ni-rare earth element-Al-based alloy sputtering target applicable to the above-described direct contact technology is concerned and even when deposition is performed at a high speed by using a Ni-rare earth element-Al-based alloy sputtering target produced according to a conventional melt-casting method, generation of splash can be effectively suppressed, and variability of the deposition rate in the sputtering deposition process can be reduced. As a result, it has been found that the desired object can be attained by appropriately controlling the crystallographic orientation in the normal direction of the sputtering surface of the Ni-rare earth element-Al-based alloy sputtering target. The present invention has been accomplished based on this finding.

In the description of the present invention, the term “capable of suppressing (reducing) generation of splash” means that when a sputtering power is set according to the deposition rate under the conditions described later in Examples and sputtering is performed, the number of splashes generated (the average value of three portions, that is, a surface part, a ¼×t part and a ½×t part, of the sputtering target) is 21 Number/cm² or less (preferably 11 Number/cm² or less, more preferably 7 Number/cm² or less). In the present invention, splash generation tendency is evaluated for the thickness (t) direction of the sputtering target and in this point, the evaluation standard of the present invention differs from those in the techniques of Patent Documents 2 to 9 where splash generation in the thickness direction is not evaluated.

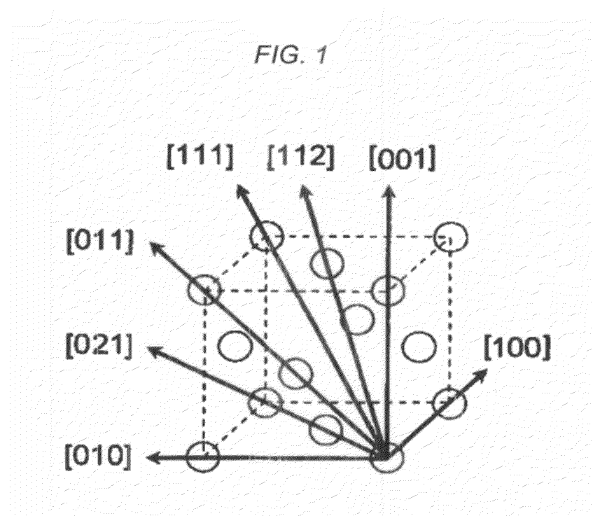

By referring to FIG. 1, crystallographic orientations that characterize the Al-based alloy sputtering target of the present invention will be described.

FIG. 1 illustrates representative crystal structure and crystallographic orientations of the Face Centered Cubic (FCC) lattice. As to the method for indicating the crystallographic orientation, a general method is employed. For example, [001], [010] and [100] are equivalent crystallographic orientations, and these three orientations are collectively indicated by <001>.

As shown in FIG. 1, Al has a crystal structure of the Face Centered Cubic (FCC) lattice and is known to mainly contain five kinds of crystallographic orientations of <011>, <001>, <111>, <012> and <112> as crystallographic orientations in a normal direction of a sputtering surface of a sputtering target (a direction toward opposite substrates (ND)). An orientation where the atomic density is highest (close packed orientation) is <011>, followed by <001>, <112>, <111> and <012> in this order.

It is considered that, among Al-based alloys and pure Al, the Al-based alloys are particularly different in solid solution/precipitation modes depending on alloy systems thereby to generate a difference between behaviors of deformation and rotation of crystals, which results in difference in crystallographic orientation formation processes. As to JIS 5000 type Al alloys (Al—Mg-based alloys) and JIS 6000 type Al alloys (Al—Mg—Si-based alloys), tendency of the crystallographic orientation and instructions of a production process, which enables to control the crystallographic orientation, are clarified. However, as to the Ni-rare earth element-Al-based alloy that is used for FPD interconnection films, electrode films and reflective electrode films, the tendency of the crystallographic orientation and instructions of a production process, which enables to control the crystallographic orientation, have not been clarified.

In Patent document 7, it is described that in the case where an Si-containing Al-based alloy sputtering target is concerned, when the ratio of crystallographic orientation of <111> is increased, the thin-film forming rate increases. Also, in paragraph [0026] of Patent Document 7, the crystal having an <111> orientation plane is stated to be, in view of its orientation, attributable to the fact that many sputtering target substances having a velocity component in the direction perpendicular to the sputtering surface are generated during sputtering.

However, according to the experiment by the present inventors, in the case where a Ni-rare earth element-Al-based alloy sputtering target is concerned as in the present invention, even when the crystallographic orientation controlling technique (technique for increasing the ratio of <111>) taught in Patent Document 7 is employed, the desired effects are not obtained.

In this connection, the present inventors have studied to provide a crystallographic orientation control technology in a Ni-rare earth element-Al-based alloy in particular among Al-based alloys.

In order to make the deposition rate faster, it is said better to control the crystallographic orientation high in leaner density of atoms constituting a sputtering target generally made of a polycrystalline structure as far as possible so as to face a substrate on which a thin film is formed. In the course of sputtering, atoms constituting a sputtering target material are knocked out due to collisions with Ar ions. The mechanism thereof is said that (a) collided Ar ions intrude in between atoms of the sputtering target to rigorously vibrate surrounding atoms, (b) the vibration is propagated in particular in a direction high in atomic density that are mutually in contact and transmitted to a surface, and (c), as the result, atoms on a surface in the direction high in atomic density are knocked out. Accordingly, it is considered that, when the close-packed directions of individual atoms constituting the sputtering target face an opposite substrate, efficient sputtering can be realized and thereby a deposition rate is heightened.

In general, it is supposed that in the same sputtering surface of a sputtering target, the erosion rate differs among grains having different crystallographic orientations and therefore, a small difference in height is formed between grains. Such a difference in height is said to be easily formed particularly when a non-uniform crystallographic orientation distribution or a coarse grain is present in the sputtering surface.

However, an atom constituting the sputtering target and being emitted into a space from the sputtering target surface is not necessarily deposited only on the opposing substrate and sometimes attaches also to the peripheral sputtering target surface to form a deposited material. This attachment or deposition is liable to occur in a part having the above-described difference in height between grains and starting from such a deposited material, splash is readily generated. As a result, the efficiency of the sputtering step and the yield of the sputtering target are considered to significantly decrease.

From the viewpoint above, the present inventors have made many studies on the relationship among the crystallographic orientation distribution of the Ni-rare earth element-Al-based alloy sputtering target, the grain size and the cause for splash generation, as a result, it has been found that the structure of a Ni-rare earth element-Al-based alloy sputtering target produced by a melt-casting method allows a non-uniform crystallographic orientation distribution or a coarse grain to be easily formed in the sputtering surface as well as in the plate thickness direction of the sputtering target.

Furthermore, it has been found that the deposition rate peculiar to the sputtering target fluctuates with time due to fluctuation of the crystallographic orientation or grain size distribution in the plate thickness direction, and when the sputtering power is increased in order to elevate the deposition rate during sputtering, splashing is liable to occur in a site where the deposition rate peculiar to the sputtering target is high, whereas when the sputtering power is decreased in order to reduce the splash, the deposition rate lowers in a site where the deposition rate peculiar to the sputtering target is low, giving rise to extreme reduction in the productivity.

As a result of further continuing investigations by the present inventors, it has been found that in a Ni-rare earth element-Al-based alloy sputtering target, when the ratios of <011>, <001> and <112> are set as high as possible and the variability thereof in the plate thickness direction of the sputtering target is minimized as much as possible, specifically, when the crystallographic orientations <001>, <011>, <111>, <012> and <112> in the normal direction of each sputtering surface at the surface part, the part of a thickness of ¼ of the plate thickness t and the part of a thickness of ½ of the plate thickness t in the plate thickness (t) direction of the Al-based alloy sputtering target are observed by an electron backscatter diffraction pattern method, (1) when the total of area fractions of the <001>±15°, <011>±15° and <112>±15° is defined as R (as for R at each part, the R at the surface part is defined as Rₐ, the R at the ¼×t part is defined as R_{b}, and the R at the ½×t part is defined as R_{c}), R is controlled to 0.35 or more and 0.8 or less (that is, all of Rₐ, R_{b} and R_{c} fall in the range of 0.35 or more and 0.80 or less) and (2) each of Rₐ, R_{b} and R_{c} is controlled to fall in the range of ±20% of the average R value [Rₐᵥₑ=(Rₐ+R_{b}+R_{c})/3], whereby the desired object can be achieved. The present invention has been accomplished based on this finding.

In the description of the present invention, the crystallographic orientation of a Ni-rare earth element-Al-based alloy is measured as follows by using an EBSD method (EBSD: Electron Backscatter Diffraction Pattern).

First, a sample for EBSD measurement is prepared by cutting an Al-based alloy sputtering target such that when the thickness of the Al-based alloy aputtering target is assumed to be t, with respect to the surface part, the ¼×t part and the ½×t part in the plate thickness direction of the sputtering target, the measuring surface (surface parallel to the sputtering surface) can ensure an area of 10 mm or more (length)×10 mm or more (width), and after the sample is subjected to polishing with emery paper or polishing with colloidal silica suspension or the like and then to electrolytic polishing with a mixed solution of perchloric acid and ethyl alcohol so as to smooth the measuring surface, the crystallographic orientation of the sputtering target above is measured using the following apparatus and software.

Apparatus: Electron backscatter diffraction pattern apparatus, “Orientation Imaging Microscopy™ (OIM™)”, manufactured by EDAX/TSL

Measurement software: OIM Data Collection ver. 5

Analysis software: OIM Analysis ver. 5

Measurement region: area 1,400 μm×1,400 μM×depth 50 nm

Step size: 8 μm

Number of visual fields measured: 3 visual fields in one measuring surface

Crystallographic orientation difference at analysis: ±15°

The “crystallographic orientation difference at analysis: ±15°” as used herein means that in analyzing, for example, the <001> crystallographic orientation, the orientation in the range of <001>±15° is deemed acceptable and judged as the <001> crystallographic orientation, because it is considered that when the crystallographic orientation is in the acceptable range above, this can be regarded as crystallographically the same orientation. As described below, in the present invention, all of the crystallographic orientations are calculated in the acceptable range of ±15°. The partition fraction of the crystallographic orientation <uvw>±15° is determined as the area fraction.

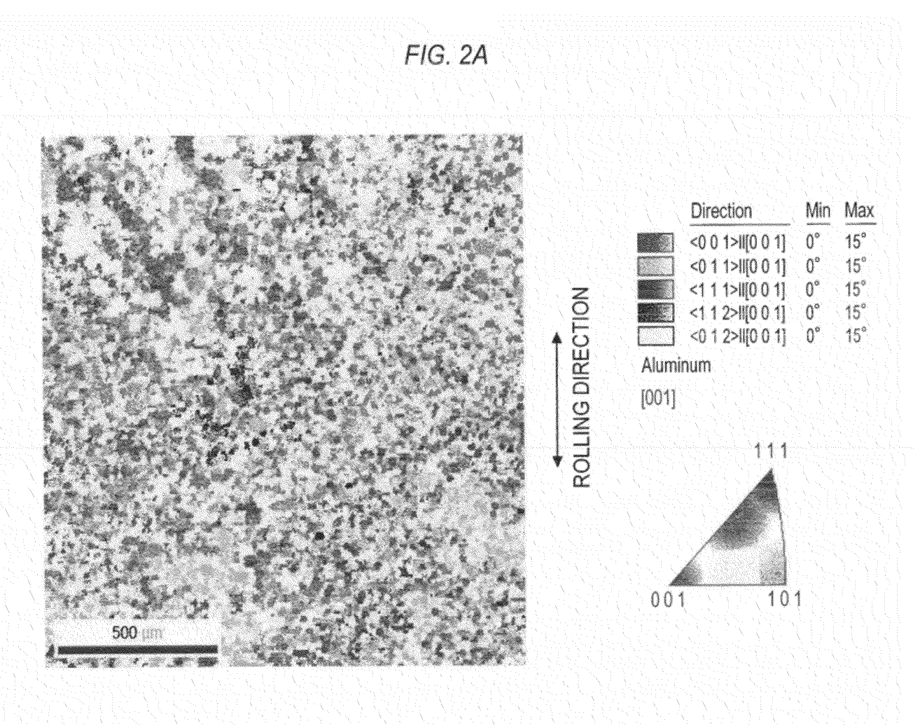

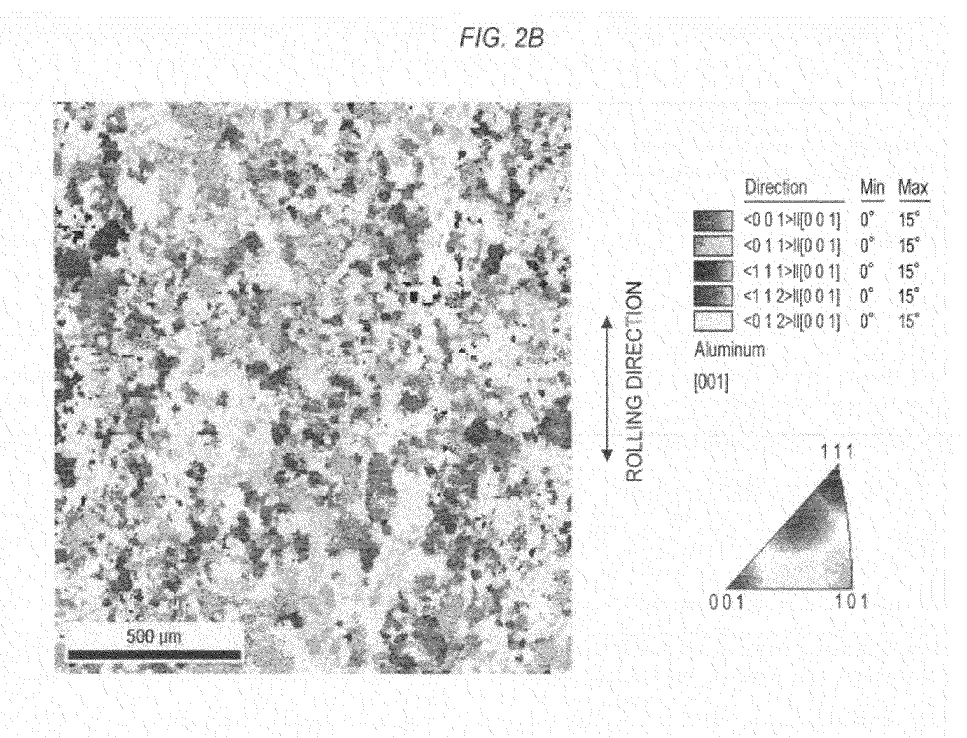

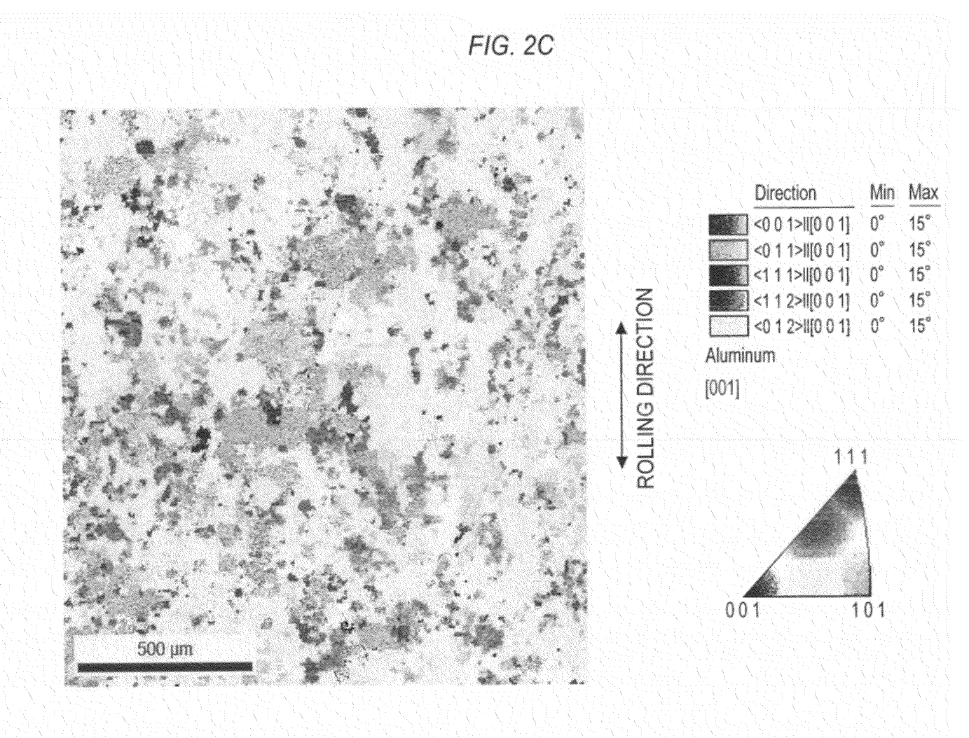

FIG. 2A is an inverse pole figure map (crystallographic orientation map) at the ¼×t part of No. 4 shown in Table 1 in the column of Example later. EBSD can discriminate grains differing in the crystallographic orientation from one another by the color tone difference. In the apparatus above, respective crystallographic orientations are identified by color, that is, <001> by red, <011> by green, <111> by blue, <112> by magenta, and <012> by yellow, but these are shown in the black-and-white schematic view of FIG. 2A.

The requirements (1) and (2) of the present invention are described below.

(1) When a total of area fractions of <001>±15°, <011>±15° and <112>±15° is defined as R (as for R at each part, the R at the surface part is defined as Rₐ, the R at the ¼×t part is defined as R_{b}, and the R at the ½×t part is defined as R_{c}), R is from 0.35 or more and 0.80 or less (that is, all of Rₐ, R_{b} and R_{c} are 0.35 or more and 0.80 or less)

The total of area fractions as used in the present invention means a total of area fractions (the ratio based on the measurement area (1,400 μm×1,400 μm)) of the above-described crystallographic orientations measured at each part of the surface part (Rₐ), the ¼×t part (R_{b}) and the ½×t part (R_{c}), and in the present invention, Rₐ to R_{c} are sometimes collectively referred to simply as R.

In the present invention, with respect to the surface part, ¼×t part and ½×t part of the Ni-rare earth element-Al-based alloy target, the area fractions of five crystallographic orientations <001>, <011>, <111>, <112> and <012> that are main crystallographic orientations present in the objective orientation direction in the normal line of the sputtering target surface are measured by the above-described EBSD method with setting of an acceptable crystallographic orientation difference of ±15° for each orientation, and the crystallographic orientation is controlled such that out of those crystallographic orientations, the total of area fractions (R) of <011>, <001> and <112> in each of the parts above, which are a crystallographic orientation having a relatively high atomic number density of an Al-based alloy, becomes 0.35 or more and 0.80 or less (that is, all of Rₐ, R_{b} and R_{c} are 0.35 or more and 0.80 or less). If the R value is less than 0.35, the crystallographic orientation distribution is inadequate or a coarse grain is formed and therefore, generation of splash cannot be effectively suppressed. On the other hand, if the R value exceeds 0.80, a coarse grain is readily formed and generation of splash cannot be suppressed. The R value is preferably controlled to be 0.4 or more and 0.75 or less, because splash generation can be more suppressed.

(2) Each of the Rₐ, R_{b} and R_{c} falls in the range of ±20% of the average R value [Rₐᵥₑ=(Rₐ+R_{b}+R_{c})/3]

Furthermore, when the thickness of the sputtering target is defined as t, the R value determined in each of three parts, that is, the surface part, the ¼×t part and the ½×t part in the plate thickness direction of the sputtering target (as for the R value at each part, the R at the surface part is defined as Rₐ, the R at the ¼×t part is defined as R_{b} and the R at ½×t part is defined as R_{c}), falls in the range of ±20% of the average R value [Rₐᵥₑ=(Rₐ+R_{b}+R_{c})/3] (that is, all of Rₐ, R_{b} and R_{c} fall in the range of Rₐᵥₑ±20%). If the R value (Rₐ, R_{b}, R_{c}) at each measurement position deviates from the range of ±20% of the average R value Rₐᵥₑ, the crystallographic orientation distribution in the normal direction of the sputtering surface varies and the deposition rate of the sputtering target becomes unstable with the passage of time, as a result, variability of the deposition rate may be produced in the sputtering deposition process or the splash occurrence frequency may be increased.

The ratio of crystallographic orientations (<111>, <012>) as the measuring object of the present invention except for the above-described <011>, <001> and <112> is not particularly limited. For suppressing generation of splash or enhancing the deposition rate, only the crystallographic orientations of <011>, <001> and <112> have to be controlled to satisfy the above requirements (1) and (2), and it was experimentally confirmed that the effect by other crystallographic orientations (<111>, <012>) need not be substantially taken into consideration.

In the foregoing, the crystallographic orientations characterizing the present invention are described.

Preferred average grain size and Vickers hardness of the Al-based alloy sputtering target of the present invention are described below.

### (Average Grain Size)

When the boundary between pixels having a crystallographic orientation difference of 15° or more as measured by the EBSD method is taken as the grain boundary, the Al-based alloy sputtering target of the present invention preferably has an average grain size of 40 μm or more and 450 μm or less.

When the crystallographic orientation data measured by the EBSD method (one visual field size: 1,400 μm×1,400 μm, step size: 8 μm) are analyzed and the boundary between pixels having a crystallographic orientation difference of 15° or more is taken as the grain boundary, the average value of equivalent-circle diameters determined from the grain size distribution of Grain Size (Diameter) output using the above-described analysis software is defined as D. When the thickness of the sputtering target is defined as t, D of each part determined in three portions, that is, the surface part, the ¼×t part and the ½×t part in the plate thickness direction of the sputtering target, is defined as Dₐ for the surface part, as D_{b} for the ¼×t part, and as D_{c} for the ½×t part. In the present invention, the “average grain size” is an average value of these D values of respective parts [Dₐᵥₑ=(Dₐ+D_{b}+D_{c})/3].

In order to more effectively bring out the splash generation preventing effect, the average grain size is preferably smaller, and specifically, the average grain size is preferably 450 μm or less, more preferably 180 μm or less, still more preferably 120 μm or less.

On the other hand, the lower limit of the average grain size may be determined with regard to the production method. That is, in the present invention, from the standpoint of, for example, reducing the production cost or the number of production steps or enhancing the yield, a melt-casting method of producing an ingot from a molten metal of Al alloy is preferred, but in the case of a melt-casting method, it is impossible to produce an Al-based alloy sputtering target having an average grain size of less than 40 μm by using general melt-casting equipment, and for this reason, the lower limit of the average grain size is set to 40 μm.

### (Vickers Hardness)

The Al-based alloy sputtering target of the present invention preferably has a Vickers hardness (HV) of 26 or more. Because the results of studies by the present inventors have revealed that when a Ni-rare earth element-Al-based alloy sputtering target is used, if the hardness of the sputtering target is low, splash is readily generated. The reason thereof is not particularly known, but if the hardness of the sputtering target is low, the microscopic smoothness of the surface finished through machining by a milling machine, a lathe or the like used for the production of the sputtering target is impaired, that is, the material surface is complicatedly deformed and roughened, as a result, a contamination such as cutting oil or the like used for the machining is incorporated into the surface of the sputtering target and remains there. Even when surface washing is performed in the later step, it is difficult to sufficiently remove such a residual contamination, and this contamination remaining on the sputtering target surface is presumed to become a starting point of splash generation. In order not to allow such a contamination to remain on the sputtering target surface, roughening of the material surface must be prevented by improving the processability (cutting) during machining. For this reason, in the present invention, the hardness of the sputtering target is preferably increased.

Specifically, from the standpoint of preventing splash generation, the Vickers hardness (HV) of the Al-based alloy sputtering target of the present invention is preferably higher and is preferably 26 or more, more preferably 35 or more, still more preferably 40 or more, yet still more preferably 45 or more. The upper limit of the Vickers hardness is not particularly limited, but if the hardness is too high, the reduction ratio of cold rolling for adjusting the hardness needs to be increased and in this case, there may arise a problem in view of production, for example, the rolling may become difficult. For this reason, the Vickers hardness is preferably 160 or less, more preferably 140 or less, still more preferably 120 or less. These upper limits and lower limits of the Vickers hardness may be arbitrarily combined to specify the range of the Vickers hardness.

In the foregoing, preferred average grain size and Vickers hardness of the Al-based alloy sputtering target of the present invention are described.

Next, the Ni-rare earth element-Al-based alloy concerned in the present invention is described below.

As described above, in the present invention, an Al-based alloy sputtering target containing Ni and a rare earth element is concerned. As described also in Patent Document 1, in the case of using a Ni-rare earth element-Al-based alloy for interconnection deposition, thanks to its excellent heat resistance, the alloy is very useful as an interconnection material for direct contact.

Ni is an element effective in reducing the electrical contact resistance between the Al-based alloy film and a pixel electrode coming into direct contact with the Al-based alloy film. This is also useful for controlling the crystallographic orientation and the grain size which are useful for preventing splash generation.

In order to bring out such actions, Ni is preferably contained at least in an amount of 0.05 atomic % or more. The content of Ni is more preferably 0.07 atomic % or more, still more preferably 0.1 atomic % or more. On the other hand, if the content of Ni is too large, the electrical resistivity of the Al-based alloy film becomes high, and therefore, the content is preferably 2.0 atomic % or less, more preferably 1.5 atomic % or less, still more preferably 1.1 atomic % or less. These upper limits and lower limits of the content of Ni may be also arbitrarily combined to specify the range of the content of Ni.

The rare earth element is an element effective in enhancing the heat resistance of an Al-based alloy film formed using the Al-based alloy sputtering target and preventing hillock formed on the Al-based alloy film surface. This is also useful for controlling the crystallographic orientation and the grain size which are useful for preventing splash generation.

In order to bring out such actions, the rare earth element is preferably contained at least in an amount of 0.1 atomic % or more. The content of the rare earth element is more preferably 0.2 atomic % or more, still more preferably 0.3 atomic % or more. If the content of the rare earth element is too large, the electrical resistivity of the Al-based alloy film becomes high, and therefore, the content is preferably 1.0 atomic % or less, more preferably 0.8 atomic % or less, still more preferably 0.6 atomic % or less. These upper limits and lower limits of the content of the rare earth element may be also arbitrarily combined to specify the range of the content of the rare earth element.

In the present invention, an Al—Ni—Al-based alloy sputtering target further containing a rare earth element such as Nd and La is also concerned. The “rare earth element” as used in the present invention means Y, lanthanoid element and actinoid element in the periodic table, and this is suitably used in particular when an Ni-rare earth element-Al-based alloy sputtering target containing La or Nd is used. One of rare earth elements may be contained alone, or two or more thereof may be used in combination. In the case of using two or more rare earth elements in combination, the total content of the rare earth elements is preferably controlled to fall in the range above.

It is also preferred to incorporate Ge into the Al-based alloy sputtering target of the present invention. Ge is an element effective in enhancing the corrosion resistance of an Al-based alloy film formed using the Al-based alloy sputtering target of the present invention. This is also useful for controlling the crystallographic orientation and the grain size which are useful for preventing splash generation.

In order to bring out such actions, Ge is preferably contained at least in an amount of 0.10 atomic % or more. The content of Ge is more preferably 0.2 atomic % or more, still more preferably 0.3 atomic % or more. If the content of Ge is too large, the electrical resistivity of the Al-based alloy film becomes high, and therefore, the content of Ge is preferably 1.0 atomic % or less, more preferably 0.8 atomic % or less, still more preferably 0.6 atomic % or less. These upper limits and lower limits of the content of Ge may be also arbitrarily combined to specify the range of the content of Ge.

Furthermore, it is also preferred to incorporate Ti and B into the Al-based alloy of the present invention, in addition to Ni, the rare earth element and preferably Ge. Ti and B are elements contributing to grain refining, and thanks to the addition of Ti and B, the latitude (acceptable range) of production conditions is expanded. However, if added excessively, the electrical resistivity of the Al-based alloy film may become high. For this reason, the content of Ti is preferably 0.0002 atomic % or more, more preferably 0.0004 atomic % or more, and is preferably 0.012 atomic % or less, more preferably 0.006 atomic % or less. These upper limits and lower limits of the content of Ti may be also arbitrarily combined to specify the range of the content of Ti. Also, the content of B is preferably 0.0002 atomic % or more, more preferably 0.0004 atomic % or more, and is preferably 0.012 atomic % or less, more preferably 0.006 atomic % or less. These upper limits and lower limits of the content of B may be also arbitrarily combined to specify the range of the content of B.

When adding Ti and B, a usually employed method can be used, and typically, these elements may be added as an Al—Ti—B refiner into the molten metal. The composition of Al—Ti—B is not particularly limited as long as the desired Al-based alloy sputtering target is obtained, but, for example, Al-5 mass % Ti-1 mass % B, and Al-5 mass % Ti-0.2 mass % B can be used. A commercial product may be used for such a refiner.

As to the components of the Al-based alloy for use in the present invention, it is preferred to contain Ni and a rare earth element, with a remainder being Al and an unavoidable impurity, it is more preferred to contain Ni, a rare earth element and Ge, with a remainder being Al and an unavoidable impurity, and it is still more preferred to contain Ni, a rare earth element, Ge, Ti and B, with a remainder being Al and an unavoidable impurity. The unavoidable impurity includes elements inevitably mixed during the production process or the like, and examples thereof include Fe, Si, C, O and N. As for the contents thereof, the content of each element is preferably 0.05 atomic % or less.

In the foregoing, a Ni-rare earth element-Al-based alloy that is the concern of the present invention is described.

### (Production Method of Sputtering Target)

The method for producing the above-described Al-based alloy sputtering target is described below.

As described above, in the present invention, the Al-based alloy sputtering target is preferably produced using a melt-casting method. Particularly, in the present invention, in order to produce an Al-based alloy sputtering target in which the crystallographic orientation distribution or the grain size is properly controlled, in the process of melt-casting→(soaking, if desired)→hot rolling→annealing, it is preferred to appropriately control at least any one of soaking condition (e.g., soaking temperature, soaking time or the like), hot rolling condition (e.g., rolling start temperature, rolling end temperature, maximum rolling reduction per one pass, total rolling reduction or the like), and annealing condition (e.g., annealing temperature, annealing time or the like). After the process above, cold rolling→annealing (process of second rolling→annealing) may be performed.

Particularly, in the present invention, in order to appropriately control the Vickers hardness of the Al-based alloy sputtering target, the hardness is preferably adjusted by performing the above-described process of second rolling→annealing, and, for example, controlling the cold rolling conditions (e.g., cold rolling reduction or the like).

However, the applicable crystallographic orientation distribution, controlling means of grain size and adjusting means of hardness vary depending on the kind of the Al-based alloy and therefore, it may be sufficient to employ appropriate means, for example, by using these means individually or in combination according to the kind of the Al-based alloy. A preferred production method of the Al-based alloy target of the present invention is described in detail below for each step.

### (Melt-Casting)

The melt-casting step is not particularly limited, and a step usually used for the production of a sputtering target may be appropriately employed to make a Ni-rare earth element-Al-based alloy ingot. Representative examples of the casting method include DC (semicontinuous) casting and continuous sheet casting (e.g., twin roll, belt caster, properzi, block caster and the like).

### (Soaking, if Desired)

After a Ni-rare earth element-Al-based alloy ingot is made as above, hot rolling is performed, but soaking may be also performed, if desired. In order to control the crystallographic orientation distribution and the grain size, the soaking temperature is preferably controlled to approximately from 300 to 600° C. (more preferably from 400 to 550° C.), and the soaking time is preferably controlled to approximately from 1 to 8 hours (more preferably from 4 to 8 hours).

### (Hot Rolling)

After performing the soaking as needed, hot rolling is performed. It is preferred for controlling the crystallographic orientation distribution and the grain size to appropriately control the hot rolling start temperature. If the hot rolling start temperature is too low, the deformation resistance may be increased, and rolling cannot be sometimes continued until a desired plate thickness is obtained. The hot rolling start temperature is preferably 210° C. or more, more preferably 220° C. or more, still more preferably 230° C. or more. On the other hand, if the hot rolling start temperature is too high, for example, the crystallographic orientation distribution in the normal direction of the sputtering surface may vary or the grain size may be coarsened, leading to increase in the number of splashes generated. The hot rolling start temperature is preferably 410° C. or less, more preferably 400° C. or less, still more preferably 390° C. or less. These upper limits and lower limits of the hot rolling start temperature may be arbitrarily combined to specify the range of the hot rolling start temperature.

If the hot rolling end temperature is too high, the crystallographic orientation distribution in the normal direction of the sputtering surface may vary or the grain size may be coarsened, and therefore, the hot rolling end temperature is preferably 220° C. or less, more preferably 210° C. or less, still more preferably 200° C. or less. On the other hand, if the hot rolling end temperature is too low, the deformation resistance may be increased, and rolling cannot be sometimes continued until a desired plate thickness is obtained. For this reason, the hot rolling end temperature is preferably 50° C. or more, more preferably 70° C. or more, still more preferably 90° C. or more. These upper limits and lower limits of the hot rolling end temperature may be arbitrarily combined to specify the range of the hot rolling end temperature.

If the maximum rolling reduction per one pass during hot rolling is too low, the crystallographic orientation distribution in the normal direction of the sputtering surface may vary or the grain size may be coarsened, leading to increase in the number of splashes generated. The maximum rolling reduction per one pass is preferably 3% or more, more preferably 6% or more, still more preferably 9% or more. On the other hand, if the maximum rolling reduction per one pass is too high, the deformation resistance may be increased and rolling cannot be sometimes continued until a desired plate thickness is obtained. The maximum rolling reduction per one pass is preferably 25% or less, more preferably 20% or less, still more preferably 15% or less. These upper limits and lower limits of the maximum rolling reduction per one pass may be arbitrarily combined to specify the range of the maximum rolling reduction per one pass.

If the total rolling reduction is too low, the crystallographic orientation distribution in the normal direction of the sputtering surface may vary or the grain size may be coarsened, leading to increase in the number of splashes generated. The total rolling reduction is preferably 68% or more, more preferably 70% or more, still more preferably 75% or more. On the other hand, if the total rolling reduction is too high, the deformation resistance may be increased and rolling cannot be sometimes continued until a desired plate thickness is obtained. The total rolling reduction is preferably 95% or less, more preferably 90% or less, still more preferably 85% or less. These upper limits and lower limits of the total rolling reduction may be arbitrarily combined to specify the range of the total rolling reduction.

Here, the rolling reduction per one pass and the total rolling reduction are represented by the following formulae, respectively:

Rolling reduction per one pass (%)={(thickness before one pass rolling)−(thickness after one pass rolling)}/(thickness before one pass rolling)×100

Total rolling reduction (%)={(thickness before start of rolling)−(thickness after end of rolling)}/(thickness before start of rolling)×100

### (Annealing)

After performing the hot rolling in this way, annealing is performed. From the standpoint of controlling the crystallographic orientation distribution and the grain size, the annealing temperature is preferably 450° C. or less, because if the annealing temperature is high, the grain size tends to be coarsened. Also, if the annealing temperature is too low, a desired crystallographic orientation may not be obtained or a coarse grain may remain due to failure in refining the grain. For this reason, the annealing temperature is preferably 250° C. or more (more preferably from 300 to 400° C.). The annealing time is preferably controlled to approximately from 1 to 10 hours (more preferably from 2 to 4 hours).

### (Cold Rolling→Annealing, if Desired)

The crystallographic orientation distribution and the grain size of the Ni-rare earth element-Al-based alloy sputtering target can be controlled by the above-described production method, but thereafter, cold rolling→annealing (second rolling, annealing) may be performed. From the standpoint of controlling the crystallographic orientation distribution and the grain size, the cold rolling conditions are not particularly limited, but the annealing conditions are preferably controlled. For example, it is recommended to control the annealing temperature to from 150 to 250° C. (more preferably from 180 to 220° C.) and the annealing temperature to from 1 to 5 hours (more preferably from 2 to 4 hours).

On the other hand, in order to control the hardness of the Ni-rare earth element-Al-based alloy sputtering target, if the rolling reduction in the cold rolling is too low, the hardness cannot be sufficiently increased, and therefore, the rolling reduction is preferably 15% or more, more preferably 20% or more. On the other hand, if the rolling reduction is too high, the deformation resistance is increased, and rolling cannot be continued until a desired plate thickness is obtained. For this reason, the rolling reduction is preferably 35% or less, more preferably 30% or less. These upper limits and lower limits of the rolling reduction may be arbitrarily combined to specify the range of the rolling reduction.

### EXAMPLES

The present invention is described in greater detail below by referring to Examples, but the present invention is not limited to these Examples and can be performed by appropriately making modifications therein as long as the purport of the present invention is observed, and these are all included in the technical range of the invention.

### Example 1

Various Ni-rare earth element-Al-based alloys shown in Table 1 were prepared, and each alloy was made into an ingot with a thickness of 100 mm by a DC casting method and then subjected to hot rolling and an annealing under the conditions shown in Table 1, thereby producing a rolled plate. For reference, the thickness of the rolled plate produced is shown in Table 1.

In this connection, the Ni-rare earth element-Al-based alloy containing Ti and B was produced by adding Ti and B in the form of a refiner (Al-5 mass % Ti-1 mass % B) to the molten metal. For example, when producing the Ni-rare earth element-Al-based alloy of No. 5 (Ti: 0.0005 atomic %, B: 0.0005 atomic %) in Table 1, the refiner above was added in a ratio of 0.02 mass % based on the mass of the entire Ni-rare earth element-Al-based alloy. Also, when producing the Ni-rare earth element-Al-based alloy of No. 6 (Ti: 0.0046 atomic %, B: 0.0051 atomic %) in Table 1, the refiner above was added in a ratio of 0.2 mass % based on the mass of the entire Ni-rare earth element-Al-based alloy.

Furthermore, the rolled plate was subjected to cold rolling and annealing (at 200° C. for 2 hours). In this connection, with respect to Nos. 1 to 6 and 9 to 22, the cold rolling reduction during the cold rolling was set to 22%, and with respect to others, that is, Nos. 7 and 8, the cold rolling reduction was set to 5%.

Subsequently, machining (cut machining work and lathe machining work) was performed to produce 3 pieces of disk-shaped Ni-rare earth element-Al-based alloy sputtering target (size: diameter 101.6 mm×thickness 5.0 mm) from one rolled plate, where the thickness was adjusted by lather machining work such that each of the surface part, the ¼×t part and the ½×t part in the thickness (t) direction of the rolled plate serves as the sputtering surface.

### (Crystallographic Orientation and Average Grain Size)

Using the sputtering target above, the crystallographic orientation in the normal direction of the sputtering surface was measured based on the above-described EBSD method and analyzed to determine the Rₐ, R_{b}, R_{c} and Rₐᵥₑ values and the average grain size. When any one value of Rₐ, R_{b} and R_{c} deviates from Rₐᵥₑ±20%, this was judged that the variability of the R value in the thickness direction of the sputtering target is wide.

### (Vickers Hardness)

The Vickers hardness (HV) of the sputtering target above was measured using a Vickers hardness apparatus (AVK-G2, manufactured by Akashi Seisakusho K.K.).

Also, using the sputtering target above, the deposition rate during sputtering and the rate of splash generation were measured.

### (Measurement of Deposition Rate)

Sputtering was performed under the following conditions to deposit a thin film on a glass substrate. The thickness of the obtained thin film was measured by a stylus film thickness meter.

Sputtering apparatus: HSR-542S manufactured by Shimadzu Corporation

Sputtering conditions:
Back pressure: 3.0×10⁻⁶ Torr or less,
Ar gas pressure: 2.25×10⁻³ Torr,
Ar gas flow rate: 30 sccm,
Sputtering power: DC260 W,
Distance between substrate and sputtering target: 52 mm,
Substrate temperature: room temperature,
Sputtering time: 120 seconds
Glass substrate: #1737 manufactured by CORNING (diameter: 50.8 mm, thickness: 0.7 mm)
Stylus film thickness meter: alpha-step 250 manufactured by

Tencor Instruments

The deposition rate was calculated based on the following formula.

Deposition rate (nm/s)=thickness (nm) of thin film/sputtering time (s)

In each of Examples, the deposition rate was a high-speed deposition of 2.2 nm/s or more and measured at arbitrary three portions, and when the deposition rate at each measurement position fluctuates by 8% or more from the average value thereof, this was judged as having variability of the deposition rate.

### (Measurement of Number of Splashes Generated)

In this Example, the number of splashes generated was measured for the splash that is liable to occur under high sputtering power condition, and splash generation was evaluated.

First, with respect to the surface part of the sputtering target of No. 4 shown in Table 1, a thin film was deposited at a deposition rate of 2.74 nm/s. Here, the Y value as a product of the deposition rate and the sputtering power DC is as follows:

Y value=deposition rate (2.74 nm/s)×sputtering power (260 W)=713

Next, with respect to the sputtering target shown in Table 1, the sputtering power DC according to the deposition rate shown together in Table 1 was set based on the Y value (constant) above, and sputtering was performed.

For example, the sputtering conditions for the surface part of the sputtering target of No. 6 are as follows.

Deposition rate: 2.77 nm/s

The sputtering power DC was set to 257 W based on the following formula:

Sputtering power DC=Y value (713)/deposition rate (2.77)=about 257 W.

In this way, the step of performing the sputtering was continuously performed while changing the glass substrate, and 16 pieces of thin film were formed per one piece of sputtering target. Accordingly, the sputtering was performed for 120 (seconds)×16 (pieces)=1,920 seconds.

Thereafter, the positional coordinate, size (average particle diameter) and number, of particles observed on the surface of the thin film were measured using a particle counter (wafer surface inspection apparatus, WM-3, manufactured by Topcon Corporation). In this case, those having a size of 3 μm or more were regarded as a particle. Then, the thin film surface was observed by an optical microscope (magnification: 1,000 times) and by regarding those having a semi-spherical shape as a splash, the number of splashes per unit area was counted.

With respect to 16 pieces of thin film above, the number of splashes was counted in the same manner at three position, that is, the surface part, ¼×t part and ½×t part, of the sputtering target, and the average value of numbers of splashes counted at three measured portions was taken as the “number of splashes generated”. In this Example, rating was AA when the thus-obtained number of splashes is 7 Number/cm² or less, A when the number is from 8 to 11 Number/cm², B when the number is from 12 to 21 Number/cm², and C when the number is 22 Number/cm² or more. In this Example, when the number of splashes generated was 21 Number/cm² or less (ratings AA, A and B), this was rated as having an effect of inhibiting splash generation (judged as passed).

### (Measurement of Electrical Resistivity)

The measurement sample for electrical resistivity of thin film was produced by the following procedure. On the surface of the thin film above, a positive photoresist (novolak resin, TSMR-8900, manufactured by Tokyo Ohka Kogyo Co., Ltd., thickness: 1.0 μm, line width: 100 μm) was formed in a stripe pattern shape by photolithography and then processed by wet etching into a pattern profile for electrical resistivity measurement, having a line width of 100 μm and a line length of 10 mm. In the wet etching, a mixed solution of H₃PO₄:HNO₃:H₂O=75:5:20 was used. For imparting a heat hysteresis, a heat treatment of holding the sample at 250° C. for 30 minutes by using a reduced-nitrogen atmosphere (pressure: 1 Pa) in a CVD apparatus was performed after the etching treatment. Thereafter, the electrical resistivity was measured at room temperature by a four probe method, and the sample was rated good (A) when the electrical resistivity was 5.0 μΩcm or less, and rated bad (C) when the electrical resistivity was more than 5.0 μΩcm.

From these results of the sputtering target properties and the thin film properties, overall performance was evaluated and taken as “comprehensive judgment”. When rating of the sputtering target properties was AA, A or B and rating of the thin film properties was A, these were rated AA, A or B without change. When rating of the sputtering target properties was AA, A or B and rating of the thin film properties was C, all were rated C. When rating of the sputtering target properties was C and rating of the thin film properties was A, these were rated C. When rating of the sputtering target properties was C and rating of the thin film properties was C, these were rated C.

These test results are shown together in Tables 1 and 2.

TABLE 1

| | | | | | | Production Conditions | | | | | | | | |
|---|---|---|---|---|---|---|---|---|---|---|---|---|---|---|
| | | | | | | | | Rolling | Rolling | Maximum | Total | | | Plate |
| | Composition (unit: atomic | | | | | Soaking | | Start | End | Rolling | Rolling | Annealing | | Thickness |
| | %, remainder: Al and | | | | | Tempera- | Soaking | Tempera- | Tempera- | Reduction | Reduc- | Tempera- | Annealing | After |
| | unavoidable impurity) | | | | | ture | Time | ture | ture | per One | tion | ture | Time | Production |
| No. | Ni | Ge | Nd | Ti | B | (° C.) | (hr) | (° C.) | (° C.) | Pass (%) | (%) | (° C.) | (hr) | (mm) |
| 1 | 0.02 | 0.50 | 0.20 | — | — | — | — | 380 | 195 | 6 | 60 | 450 | 4 | 31.2 |
| 2 | 0.05 | 0.50 | 0.20 | 0.0005 | 0.0005 | — | — | 360 | 179 | 11 | 75 | 500 | 2 | 19.5 |
| 3 | 0.05 | 0.50 | 0.20 | — | — | — | — | 240 | 164 | 16 | 75 | 300 | 2 | 19.5 |
| 4 | 0.10 | 0.50 | 0.20 | — | — | — | — | 250 | 147 | 14 | 86 | 300 | 2 | 10.9 |
| 5 | 0.10 | 0.50 | 0.20 | 0.0005 | 0.0005 | — | — | 250 | 149 | 11 | 82 | 350 | 2 | 14.0 |
| 6 | 0.10 | 0.50 | 0.20 | 0.0046 | 0.0051 | — | — | 250 | 145 | 14 | 86 | 350 | 2 | 10.9 |
| 7 | 0.10 | 0.50 | 0.20 | — | — | — | — | 360 | 144 | 4 | 70 | 400 | 4 | 28.5 |
| 8 | 0.10 | 0.50 | 0.20 | — | — | — | — | 420 | 196 | 11 | 75 | 450 | 2 | 23.8 |
| 9 | 0.10 | 0.50 | 0.20 | — | — | — | — | 520 | 244 | 11 | 60 | 300 | 2 | 31.2 |
| 10 | 0.10 | 0.50 | 0.20 | — | — | — | — | 450 | 124 | 1 | 70 | 400 | 4 | 23.4 |
| 11 | 0.10 | 0.50 | 0.20 | — | — | — | — | 380 | 194 | 11 | 40 | 450 | 2 | 46.8 |
| 12 | 0.10 | 0.05 | 0.20 | — | — | — | — | 400 | 213 | 6 | 60 | 350 | 2 | 31.2 |
| 13 | 0.10 | 0.10 | 0.20 | — | — | — | — | 360 | 180 | 14 | 86 | 350 | 2 | 10.9 |
| 14 | 0.10 | 1.00 | 0.20 | — | — | — | — | 240 | 133 | 11 | 75 | 300 | 2 | 19.5 |
| 15 | 0.10 | 1.20 | 0.20 | 0.0046 | 0.0051 | — | — | 250 | 147 | 11 | 60 | 350 | 2 | 31.2 |
| 16 | 0.10 | 0.50 | 0.05 | — | — | — | — | 400 | 195 | 4 | 65 | 400 | 4 | 27.3 |
| 17 | 0.10 | 0.50 | 0.10 | 0.0005 | 0.0005 | — | — | 240 | 128 | 11 | 82 | 300 | 2 | 14.0 |
| 18 | 0.10 | 0.50 | 1.00 | — | — | — | — | 250 | 136 | 11 | 75 | 300 | 2 | 19.5 |
| 19 | 0.10 | 0.50 | 1.20 | — | — | — | — | 360 | 191 | 16 | 86 | 350 | 2 | 10.9 |
| 20 | 1.00 | 0.50 | 0.20 | — | — | — | — | 380 | 179 | 11 | 74 | 350 | 2 | 20.3 |
| 21 | 2.00 | 0.50 | 0.20 | 0.0005 | 0.0005 | 520 | 8 | 360 | 149 | 6 | 65 | 400 | 2 | 27.3 |
| 22 | 3.00 | 0.50 | 0.20 | — | — | 500 | 4 | 380 | 156 | 6 | 74 | 400 | 2 | 20.3 |

TABLE 2

| | Structure of Sputtering Target | | | | | | Sputtering Target Properties | | | | | | |
|---|---|---|---|---|---|---|---|---|---|---|---|---|---|
| | | | | | Average | | | | Number of | | Thin Film Properties | | |
| | | | | | Grain | Hard- | Deposition | Range of | splashes | | Electrical | | Compre- |
| | | | | | Size | ness | Rate | Deposition | Generated | | Resistivity | | hensive |
| No. | Rₐ | R_{b} | R_{c} | Rₐᵥₑ | (μm) | (HV) | (nm/s) | Rate | (Number/cm²) | Judgment | (μΩcm) | Judgment | Judgment |
| 1 | 0.49 | 0.79 | 0.84 | 0.71 | 1034 | 44.3 | 2.84 | 2.61 to 2.97 | 23 | C | 3.5 | A | C |
| 2 | 0.62 | 0.50 | 0.50 | 0.54 | 473 | 36.6 | 2.61 | 2.52 to 2.78 | 15 | B | 3.5 | A | B |
| 3 | 0.49 | 0.56 | 0.52 | 0.53 | 127 | 41.7 | 2.58 | 2.51 to 2.65 | 8 | A | 3.5 | A | A |
| 4 | 0.63 | 0.59 | 0.56 | 0.59 | 197 | 39.8 | 2.71 | 2.66 to 2.74 | 10 | A | 3.5 | A | A |
| 5 | 0.59 | 0.58 | 0.53 | 0.57 | 76 | 43.7 | 2.77 | 2.71 to 2.83 | 5 | AA | 3.5 | A | AA |
| 6 | 0.58 | 0.49 | 0.59 | 0.55 | 70 | 36.7 | 2.75 | 2.69 to 2.78 | 6 | AA | 3.5 | A | AA |
| 7 | 0.53 | 0.43 | 0.43 | 0.46 | 179 | 23.8 | 2.63 | 2.50 to 2.79 | 14 | B | 3.5 | A | B |
| 8 | 0.64 | 0.46 | 0.46 | 0.52 | 573 | 25.2 | 2.56 | 2.43 to 2.70 | 19 | B | 3.5 | A | B |
| 9 | 0.52 | 0.24 | 0.27 | 0.34 | 668 | 35.3 | 2.46 | 2.24 to 2.79 | 28 | C | 3.5 | A | C |
| 10 | 0.89 | 0.41 | 0.44 | 0.58 | 856 | 37.5 | 2.70 | 2.51 to 3.07 | 25 | C | 3.5 | A | C |
| 11 | 0.39 | 0.30 | 0.27 | 0.32 | 769 | 36.2 | 2.47 | 2.23 to 2.63 | 26 | C | 3.5 | A | C |
| 12 | 0.68 | 0.85 | 0.93 | 0.82 | 514 | 39.2 | 2.86 | 2.61 to 3.05 | 23 | C | 3.4 | A | C |
| 13 | 0.64 | 0.56 | 0.57 | 0.59 | 180 | 42.3 | 2.71 | 2.65 to 2.82 | 8 | A | 3.7 | A | A |
| 14 | 0.49 | 0.59 | 0.50 | 0.53 | 125 | 39.4 | 2.58 | 2.51 to 2.61 | 9 | A | 4.8 | A | A |
| 15 | 0.53 | 0.55 | 0.49 | 0.52 | 95 | 44.6 | 2.57 | 2.51 to 2.62 | 6 | AA | 5.2 | C | C |
| 16 | 0.63 | 0.86 | 0.94 | 0.81 | 637 | 38.1 | 2.84 | 2.58 to 2.97 | 24 | C | 3.4 | A | C |
| 17 | 0.58 | 0.61 | 0.55 | 0.58 | 116 | 37.3 | 2.68 | 2.63 to 2.75 | 9 | A | 3.6 | A | A |
| 18 | 0.50 | 0.58 | 0.50 | 0.53 | 138 | 43.4 | 2.58 | 2.52 to 2.70 | 10 | A | 4.6 | A | A |
| 19 | 0.55 | 0.51 | 0.51 | 0.52 | 153 | 38.8 | 2.57 | 2.54 to 2.63 | 10 | A | 5.2 | C | C |
| 20 | 0.53 | 0.52 | 0.56 | 0.54 | 112 | 35.0 | 2.60 | 2.57 to 2.64 | 9 | A | 4.0 | A | A |
| 21 | 0.63 | 0.63 | 0.59 | 0.62 | 85 | 44.7 | 2.73 | 2.66 to 2.77 | 8 | A | 4.8 | A | A |
| 22 | 0.71 | 0.72 | 0.75 | 0.73 | 107 | 38.0 | 2.98 | 2.96 to 2.99 | 4 | AA | 5.6 | C | C |

Table 1 reveals the followings.

In No. 2 which is an example where the alloy composition, the crystallographic orientation distribution (the ranges of Rₐ to R_{c} values and Rₐᵥₑ value) and the Vickers hardness satisfy the requirements of the present invention, the number of splashes generated was suppressed to 21 Number/cm² or less and an effect of suppressing generation of splash was recognized. However, in No. 2, since the annealing temperature exceeded the upper limit (450° C.) recommended in the present invention and the average grain size exceeded the upper limit (450 μm) recommended in the present invention, the effect of suppressing generation of splash was low as compared with examples where the average particle grain size was controlled to fall in the preferred range.

In No. 7 which is an example where the alloy composition, the crystallographic orientation distribution and the average grain size satisfy the requirements of the present invention, the number of splashes generated was suppressed to 21 Number/cm² or less and an effect of suppressing generation of splash was recognized. However, in No. 7, since the cold rolling reduction was less than the lower limit (15%) recommended in the present invention, the Vickers hardness was less than 26, and the effect of suppressing generation of splash was low as compared with examples where the Vickers hardness was controlled to 26 or more.

In No. 8 which is an example where the alloy composition and the crystallographic orientation distribution satisfy the requirements of the present invention, the number of splashes generated was suppressed to 21 Number/cm² or less and an effect of suppressing generation of splash was recognized. However, in No. 8, since the rolling start temperature exceeded the upper limit (410° C.) recommended in the present invention and the average grain size exceeded the upper limit (450 μm) recommended in the present invention and furthermore, since the cold rolling reduction is less than the lower limit (15%) recommended in the present invention, the variability of the R value in the thickness direction of the sputtering target was widened and the Vickers hardness was less than 26, as a result, the effect of suppressing generation of splash was low as compared with examples where the average particle grain size and the Vickers hardness were controlled to fall in the preferred ranges.

In Nos. 3 to 6, 13, 14, 17, 18, 20 and 21 which are examples where the cold rolling reduction in the second rolling was appropriately controlled, the Vickers hardness as well as the alloy composition and the average grain size satisfy the requirements recommended in the present invention. Therefore, the number of splashes generated was more suppressed (number of splashes generated: 11 Number/cm² or less) and a higher effect of suppressing generation of splash was recognized.

On the other hand, in the following examples where any one of the requirements of the present invention is not satisfied, splash generation could not be effectively prevented.

Specifically, No. 1 is an example of producing the target under the conditions where the Ni amount was small and the total rolling reduction was less than the lower limit (68%) recommended in the present invention. In this Example, the total of area fractions of R_{c} exceeded 0.80, the variability of the R value in the thickness direction of the sputtering target was widened, the grain size was coarsened, and the number of splashes generated was increased.

No. 9 is an example of producing the target under the conditions where the hot rolling start temperature (410° C.) and the rolling end temperature (220° C.) were a temperature higher than the upper limit recommended in the present invention and the total rolling reduction was less than the lower limit (68%) recommended in the present invention. In this Example, the total of area fractions of each of R_{b} and R_{c} was less than 0.35, the variability of the R value in the thickness direction of the sputtering target was widened, the grain size was coarsened, and the number of splashes generated was increased. Also, the deposition rate varied.

No. 10 is an example of producing the target under the conditions where the maximum rolling reduction per one pass during hot rolling was less than the lower limit (3%) recommended in the present invention and the rolling start temperature exceeded the upper limit (410° C.) recommended in the present invention. The total of area fractions of Rₐ exceeded 0.80, the variability of the R value in the thickness direction of the sputtering target was widened, the grain size was coarsened, and the number of splashes generated was increased.

No. 11 is an example of producing the target under the conditions where the total rolling reduction during hot rolling was less than the lower limit (68%) recommended in the present invention. The total of area fractions of each of R_{b} and R_{c} was less than 0.35, the variability of the R value in the thickness direction of the sputtering target was widened, the grain size was coarsened, and the number of splashes generated was increased. Also, the deposition rate varied.

No. 12 is an example of producing the target under the conditions where the Ge amount was small and the total rolling reduction during hot rolling was less than the lower limit (68%) recommended in the present invention. The total of area fractions of each of R_{b} and R_{c} exceeded 0.80, the variability of the R value in the thickness direction of the sputtering target was widened, the grain size was coarsened, and the number of splashes generated was increased. Also, the deposition rate varied.

No. 16 is an example of producing the target under the conditions where the Nd amount was small and the total rolling reduction during hot rolling was less than the lower limit (68%) recommended in the present invention. The total of area fractions of each of R_{b} and R_{c} exceeded 0.80, the variability of the R value in the thickness direction of the sputtering target was widened, the grain size was coarsened, and the number of splashes generated was increased. Also, the deposition rate varied.

Nos. 15 (Ge), 19 (Nd) and 22 (Ni) are examples where the content of the alloy element was increased. Although an effect of reducing splash was recognized, the electrical resistivity of the thin film was raised.

For reference, an inverse pole figure map (crystallographic orientation map) is shown in FIG. 2A for the ¼×t part of No. 4, in FIG. 2B for the ¼×t part of No. 5 (both are Examples of the present invention), and in FIG. 2C for the ¼×t part of No. 9 (Comparative Example). As shown in these Figures, it is seen that in No. 4 and No. 5, grains of <001>, <011> and <112> are finely dispersed, whereas in No. 9 where the crystallographic orientation is not appropriately controlled, a coarse grain is formed.

While the invention has been described in detail and with reference to specific embodiments thereof, it will be apparent to one skilled in the art that various changes and modifications can be made therein without departing from the spirit and scope thereof.

This application is based on Japanese Patent Application No. 2010-043073 filed on Feb. 26, 2010, and the entire subject matter of which is incorporated herein by reference.

### INDUSTRIAL APPLICABILITY

In the Ni-rare earth element-Al-based alloy target of the present invention, the crystallographic orientation in the normal direction of the sputtering surface is appropriately controlled, so that even when film deposition is performed at a high speed, the deposition rate can be stabilized and sputtering failure (splash) can be also effectively reduced. In this way, according to the present invention, the deposition rate can be stably maintained from the start to the substantial end of use of the target, so that splash generated at the deposition of the sputtering target or variability of the deposition rate can be greatly reduced and the productivity can be enhanced.

1. An Al-based alloy sputtering target, comprising:
Ni and
a rare earth element,
wherein, for a thickness t of the target, and for electron backscatter diffraction pattern method observations of crystallographic orientations <001>, <011>, <111>, <012>, and <112> in a normal direction of each sputtering surface at a surface part of the Al-based alloy sputtering target, a ¼×t part thereof, and a ½×t part thereof:
a value R is 0.35 or more and 0.80 or less, and
each of a value Rₐ, a value R_{b}, and a value R_{c} is independently within ±20% of an average R value [Rₐᵥₑ=(Rₐ+R_{b}+R_{c})/3];
wherein R is a total of area fractions of orientations <001>±15°, <011>±15° and <112>±15°;
Rₐ is an R at the surface part;
R_{b} is an R at the ¼×t part; and
R_{c} is an R at the ½×t part.

2. The target of claim 1, wherein an average grain size of a sputtering surface of the Al-based alloy sputtering target is from 40 to 450 μm as observed by an electron backscatter diffraction pattern method.

3. The target of claim 1,
wherein a content of Ni is from 0.05 to 2.0 atomic %, and
a content of the rare earth element is from 0.1 to 1.0 atomic %.

4. (canceled)

5. The target of claim 1, further comprising Ge.

6-8. (canceled)

9. The target of claim 5, wherein a content of Ge is from 0.10 to 1.0 atomic %.

10-12. (canceled)

13. The target of claim 1, further comprising Ti and B.

14-24. (canceled)

25. The target of claim 13,
wherein a content of Ti is from 0.0002 to 0.012 atomic %, and
a content of B is from 0.0002 to 0.012 atomic %.

26-36. (canceled)

37. The target of claim 1, wherein a Vickers hardness of the target is 26 or more.

38. The target of claim 1, wherein R is 0.4 or more and 0.75 or less.

39. The target of claim 2, wherein the average grain size is from 40 to 180 μm.

40. The target of claim 39, wherein the average grain size is from 40 to 120 μm.

41. The target of claim 37, wherein the Vickers hardness of the target is 35 or more.

42. The target of claim 1, wherein a Vickers hardness of the Al-based alloy sputtering target is 160 or less.

43. The target of claim 1, consisting of Ni, a rare earth element, Al, and optionally one or more unavoidable impurities.

44. The target of claim 1, consisting of Ni, a rare earth element, Ge, Al, and optionally one or more unavoidable impurities.

45. The target of claim 1, consisting of Ni, a rare earth element, Ge, Ti, B, Al, and optionally one or more unavoidable impurities.

46. The target of claim 43,
wherein a content of Ni is from 0.05 to 2.0 atomic %, and
a content of the rare earth element is from 0.1 to 1.0 atomic %.

47. The target of claim 44,
wherein a content of Ni is from 0.05 to 2.0 atomic %,
a content of the rare earth element is from 0.1 to 1.0 atomic %, and
a content of Ge is from 0.10 to 1.0 atomic %.

48. The target of claim 45,
wherein a content of Ni is from 0.05 to 2.0 atomic %,
a content of the rare earth element is from 0.1 to 1.0 atomic %,
a content of Ge is from 0.10 to 1.0 atomic %,
wherein a content of Ti is from 0.0002 to 0.012 atomic %, and
a content of B is from 0.0002 to 0.012 atomic %.
